(19) United States
(12) Patent Application Publication
(10) Pub. No.: US 2013/0001623 A1
(43) Pub. Date: Jan. 3, 2013

(54) LIGHT-EMITTING APPARATUS AND MANUFACTURING METHOD THEREOF

(75) Inventor: CHUN-BIN WEN, (US)

(73) Assignee: GIO Optoelectronics Corp., Tainan City (TW)

(21) Appl. No.: 13/536,963

(22) Filed: Jun. 28, 2012

(30) Foreign Application Priority Data
Jul. 1, 2011 (TW) 100123424
Feb. 2, 2012 (TW) 101103434

(51) Int. Cl. H01L 33/52; H01L 33/50

(52) U.S. Cl. 257/98; 257/100; 438/26; 257/E33.06; 257/E33.059

(57) ABSTRACT

A light-emitting apparatus includes a substrate, at least one light emitting diode (LED) die, a sealant align layer, and a first sealant. The substrate has a die disposing area. The LED die is disposed on the die disposing area. The sealant align layer is disposed on the substrate. The first sealant at least partially covers the LED die and contacts with the sealant align layer. The light-emitting apparatus can avoid the light emitted from the LED die to be blocked and can have higher light efficiency.

### CROSS REFERENCE TO RELATED APPLICATIONS

This Non-provisional application claims priority under 35 U.S.C. §119(a) on Patent Application No(s). 100123424 filed in Taiwan, Republic of China on Jul. 1, 2011, and 101103434 filed in Taiwan, Republic of China on Feb. 2, 2012, the entire contents of which are hereby incorporated by reference.

### BACKGROUND OF THE INVENTION

1. Field of Invention

The present invention relates to a light-emitting apparatus and, in particular, to a light-emitting apparatus containing light emitting diode(s) (LED).

2. Related Art

In order to increase the throughput and decrease the cost of LEDs, the packaging process of LED is usually a batch type process. For example, a plurality of LED dies are bonded on a substrate (e.g. a circuit board), and then the wire-bonding process and gluing process are performed to complete the package process of multiple LED dies in one batch.

Because of the progressive of semiconductor technology, the dimension of substrate has become smaller to fabricate more compact electronic devices. Moreover, it is necessary to configure more numbers of LED dies on a single substrate. Accordingly, the distance between adjacent LED dies becomes smaller, so that the overflow of glue during the gluing process may easily occur. If the overflow issue becomes worse, the light shape of the light emitted from the LED dies may be affected. Even worse, the electronic connection between the LED dies and the substrate may be suffered, thereby reducing the production yield.

To prevent the overflow of glue, the LED dies are disposed in a reflective housing, which serves as a barrier. Unfortunately, the height of the reflective housing can decrease the light outputting angle of the LED dies. This is undesired for the application requiring large light outputting angle.

Therefore, it is an important subject of the invention to provide a light-emitting apparatus that can properly control the overflow of glue during the gluing process without using the reflective housing to serve as the barrier of overflowed glue.

### SUMMARY OF THE INVENTION

In view of the foregoing, an objective of the invention is to provide a light-emitting apparatus that can properly control the overflow of glue without using the reflective housing to serve as the barrier of overflowed glue.

To achieve the above objective, the present invention discloses a light-emitting apparatus comprising a substrate, at least a light emitting diode (LED) die, a sealant align layer, and a first sealant. The substrate has a die disposing area, and the LED die is disposed on the die disposing area. The sealant align layer is disposed on the substrate. The first sealant at least partially covers the LED die and contacts with the sealant align layer.

To achieve the above objective, the present invention also discloses a light-emitting apparatus comprising a substrate, at least a light emitting diode (LED) die, a sealant align layer, an aligning auxiliary, and a first sealant. The substrate has a die disposing area, and the LED die is disposed on the die disposing area. The sealant align layer is disposed on the substrate, and the aligning auxiliary is disposed on the sealant align layer. The first sealant at least partially covers the LED die and contacts with the aligning auxiliary.

In one embodiment, the light-emitting apparatus further comprises a second sealant covering the LED die and the first sealant.

In one embodiment, the edge of the second sealant is substantially located at the edge of the sealant align layer.

In one embodiment, the second sealant covers the sealant align layer and is substantially located at the outer edge of the sealant align layer.

In one embodiment, the material of the sealant align layer comprises a metal, an alloy, or a solder mask.

In one embodiment, the sealant align layer is a patterned layer.

In one embodiment, the sealant align layer is disposed around the die disposing area.

In one embodiment, the sealant align layer is located within the die disposing area.

In one embodiment, the light-emitting apparatus further comprises a barrier layer disposed on the substrate, and the barrier layer and the sealant align layer are located at the same side of the substrate.

In one embodiment, a gap is disposed between the barrier layer and the sealant align layer.

In one embodiment, the material of the barrier layer comprises a metal, an alloy, or a solder mask.

In one embodiment, the light-emitting apparatus further comprises a material layer disposed on the substrate and abutting against the sealant align layer.

In one embodiment, the material of the material layer comprises a metal, an alloy, or a solder mask.

In one embodiment, the height of the material layer is smaller than that of the sealant align layer.

In one embodiment, the first sealant and/or the second sealant comprises a wavelength conversion material.

To achieve the above objective, the present invention further discloses a manufacturing method of a light-emitting apparatus, comprising the steps of: disposing a sealant align layer on a substrate; disposing at least a light emitting diode (LED) die on a die disposing area of the substrate; and disposing a first sealant for at least partially covering the LED die and contacting with the sealant align layer.

To achieve the above objective, the present invention further discloses a manufacturing method of a light-emitting apparatus, comprising the steps of: disposing a sealant align layer on a substrate; disposing at least a light emitting diode (LED) die on a die disposing area of the substrate; disposing an aligning auxiliary on the sealant align layer; and disposing a first sealant for at least partially covering the LED die and contacting with the aligning auxiliary.

In one embodiment, the manufacturing method further comprises a step of: disposing a second sealant for covering the LED die and the first sealant, wherein the edge of the second sealant is substantially located at the edge of the sealant align layer.

In one embodiment, the manufacturing method further comprises a step of: disposing a barrier layer on the substrate, wherein the barrier layer is located at the same side of the substrate as the sealant align layer.

In one embodiment, a gap is disposed between the barrier layer and the sealant align layer.

In one embodiment, the manufacturing method further comprises a step of: disposing a material layer on the substrate, wherein the material layer abuts against the sealant align layer.

As mentioned above, the light-emitting apparatus of the invention has a sealant align layer disposed on the substrate. Accordingly, it is possible to decrease the undesired glue overflow by aligning the first and/or second sealant with the sealant align layer, wherein the edge of the first and/or second sealant is substantially located at the edge of the sealant align layer. As a result, it is unnecessary to configure the reflective housing for carrying the LED die, so that the light outputting angle of the LED die is not decreased by the reflective housing, thereby enhancing the product quality.

### BRIEF DESCRIPTION OF THE DRAWINGS

The invention will become more fully understood from the detailed description and accompanying drawings, which are given for illustration only, and thus are not limitative of the present invention, and wherein:

FIG. 1 is a top view of a light-emitting apparatus according to an embodiment of the invention;

FIG. 2 is a side view of the light-emitting apparatus according to the embodiment of the invention;

FIG. 3 is a side view of another light-emitting apparatus according to the embodiment of the invention;

FIG. 4A is a side view of another light-emitting apparatus according to the embodiment of the invention;

FIG. 4B is a side view of another light-emitting apparatus with light convergence function according to the embodiment of the invention;

FIG. 4C is a side view of another light-emitting apparatus with light divergence function according to the embodiment of the invention;

FIG. 5A is a side view of another light-emitting apparatus according to the embodiment of the invention;

FIG. 5B is a side view of another light-emitting apparatus with light convergence function according to the embodiment of the invention;

FIG. 5C is a side view of another light-emitting apparatus with light divergence function according to the embodiment of the invention;

FIG. 6 is a top view of another light-emitting apparatus according to the embodiment of the invention;

FIG. 7 is a side view of another light-emitting apparatus according to the embodiment of the invention;

FIG. 8 is a side view of another light-emitting apparatus according to the embodiment of the invention;

FIG. 9 is a flow chart of a manufacturing method of a light-emitting apparatus according to an embodiment of the invention; and

FIG. 10 is a flow chart of another manufacturing method of a light-emitting apparatus according to the embodiment of the invention.

### DETAILED DESCRIPTION OF THE INVENTION

The present invention will be apparent from the following detailed description, which proceeds with reference to the accompanying drawings, wherein the same references relate to the same elements.

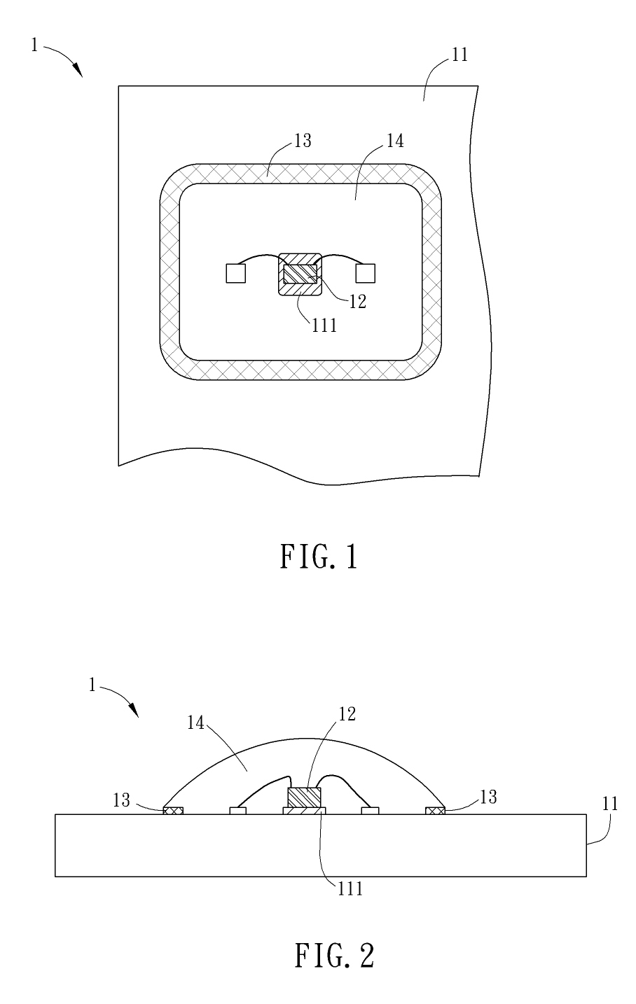

FIG. 1 is a top view of a light-emitting apparatus 1 according to an embodiment of the invention, and FIG. 2 is a side view of the light-emitting apparatus 1. With reference to FIGS. 1 and 2, the light-emitting apparatus 1 includes a substrate 11, at least one light emitting diode (LED) die 12, a sealant align layer 13, and a first sealant 14. In this embodiment, the light-emitting apparatus 1 is an illuminating device for example. Otherwise, the light-emitting apparatus 1 may also be the backlight of an LCD device, the light source of an electronic device, an indication board, or an advertising board.

The substrate 11 has a die disposing area 111. Herein, the material of the substrate 11 includes, for example but not limited to, plastic, glass, metal, alloy, ceramic or their combinations. In this embodiment, the substrate 11 is a printed circuit board containing plastic material. The die disposing area 111 is an area configured with conductive metal material or insulating material. The useable conductive metal material includes, for example, copper, silver, gold, or their combinations. In this embodiment, the die disposing area 111 is configured by copper with a silver coating, and it is used to dispose the LED die 12.

The LED die 12 is disposed on the die disposing area 111. In practice, the LED die 12 can be disposed on the die disposing area 111 by wire bonding or flip-chip bonding, and then electrically connected with the substrate 11 through the die disposing area 111. In this embodiment, the LED die 12 is disposed on the die disposing area 111 of the substrate 11 by wire bonding for example. To be noted, this embodiment discloses that one LED die 12 is disposed on the substrate 11, but in practice, it is possible to dispose multiple LED dies 12 on the substrate 11 depending on the actual requirement. The LED dies 12 are arranged in a row and disposed on a long-shaped substrate 11; otherwise, the LED dies 12 are arranged in an array, an annularity, or irregular and disposed on a substrate 11 with the shape of polygon, circle or any other shapes.

The sealant align layer 13 is disposed on the substrate 11. In this embodiment, the sealant align layer 13 is disposed around the die disposing area 111. The sealant align layer 13 is a patterned layer, and the material thereof includes a metal, an alloy, or a solder mask. In this embodiment, the material of the sealant align layer 13 includes a metal (copper) for example. Thus, the sealant align layer 13 and the conductive metal material of the die disposing area 111 can be formed by a single manufacturing process. In addition, although the sealant align layer is a structure with a certain height, this invention does not intend to use the sealant align layer 13 as the barrier for preventing the overflow of glue. Therefore, the height (thickness) of the sealant align layer 13 may be smaller than or equal to that of the conductive metal material in the die disposing area 111. This configuration can also decrease the material cost of the sealant align layer 13. In this embodiment, the height of the sealant align layer 13 is equal to that of the conductive metal material in the die disposing area 111.

The first sealant 14 is at least partially covers the LED die 12. For example, the first sealant 14 may totally cover the LED die 12 so as to protect the LED die 12. The configuration of the first sealant 14 can prevent moisture, oxygen or dust from leaking into the LED die 12, thereby maintaining the quality of the LED die 12. After the following gluing process, the melted first sealant 14 not only covers the LED die 12 but also overflows outwardly, and the overflowed first sealant 14 may contact at least a part of the sealant align layer 13.

The cohesive force allows the first sealant 14 to keep at the smallest surface area and to stay on the top surface of the sealant align layer 13. Therefore, when the melted first sealant 14 is applied too much, it may overflow and be stopped at the edge (outer edge) of the sealant align layer 13 after covering the entire LED die 12. In this case, the shape of the first sealant 14 seems like a water drop. Accordingly, it is possible to design a proper shape of the sealant align layer 13 (e.g. around the LED die 12) so as to restrict the flowing range of the first sealant 14 and/or the second sealant 16, thereby decreasing the overflow issue.

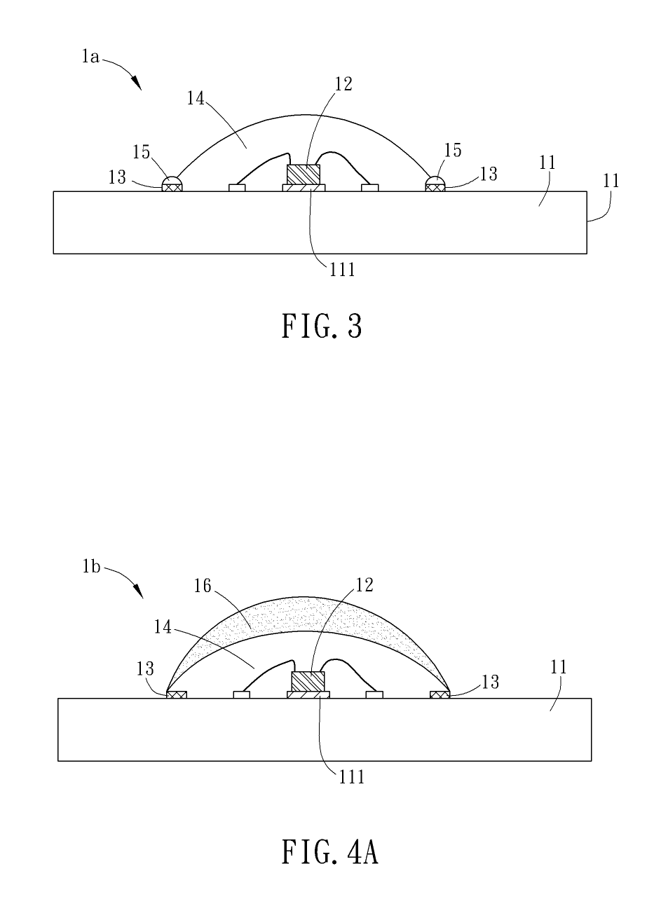

FIG. 3 is a side view of another light-emitting apparatus 1a according to the embodiment of the invention. Referring to FIG. 3, the light-emitting apparatus 1a comprises a substrate 11, at least an LED die 12, a sealant align layer 13, an aligning auxiliary 15, and a first sealant 14. Different from the above light-emitting apparatus 1, the light-emitting apparatus 1a further has an aligning auxiliary 15 disposed on the sealant align layer 13. The area of the aligning auxiliary 15 is approximately the same as that of the sealant align layer 13, or substantially larger than that of the sealant align layer 13, so that the sealant align layer 13 is covered by the aligning auxiliary 15. The material of the aligning auxiliary 15 includes resin, silica gel, or ceramic. In this embodiment, the aligning auxiliary 15 is a high-reflective resin (e.g. a white resin). The cohesive force allows the aligning auxiliary 15 to keep at the smallest surface area and to stay on the top surface of the sealant align layer 13. Therefore, although the amount of the aligning auxiliary 15 is not much, it may be stopped at the edge of the sealant align layer 13. In this case, the shape of the aligning auxiliary 15 seems like a water drop. Then, the first sealant 14 is disposed and in contact with the aligning auxiliary 15. By the configuration of the aligning auxiliary 15, the first sealant 14 can be stay within the range of the sealant align layer 13 so as to decreases the overflow issue. The other components are all illustrated hereinabove, so the detailed description thereof is omitted.

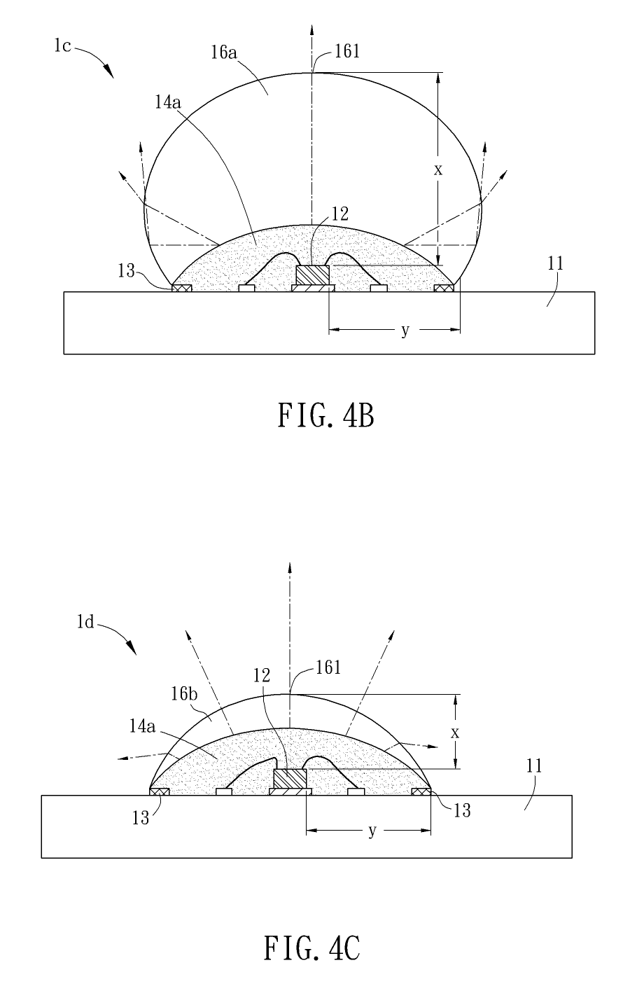

FIG. 4A is a side view of another light-emitting apparatus 1b according to the embodiment of the invention. Referring to FIG. 4A, the light-emitting apparatus 1b further includes a second sealant 16, which covers the LED die 12 and the first sealant 14. Herein, the second sealant 16 may indirectly cover the LED die 12 while the first sealant 14 has directly covered the LED die 12. When the first sealant 14 and/or the second sealant 16 flow to the edge of the sealant align layer 13, they are stopped. The edge of the sealant align layer 13 refers to the outer edge thereof. After the following curing step, the edges of the first sealant 14 and/or the second sealant 16 are substantially located at the edge of the sealant align layer 13. This is because that the cohesive force allows the first sealant 14 and/or the second sealant 16 to keep at the smallest surface area and to stay on the top surface of the sealant align layer 13. Therefore, when the melted first sealant 14 and/or the second sealant 16 are applied too much, they may overflow outwardly and be stopped at the edge of the sealant align layer 13. In this case, the shapes of the first sealant 14 and/or the second sealant 16 seem like a water drop. Accordingly, it is possible to design a proper shape of the sealant align layer 13 (e.g. around the LED die 12) so as to restrict the flowing range of the first sealant 14 and/or the second sealant 16, thereby decreasing the overflow issue. In addition, the first sealant 14 and/or the second sealant 16 may further include at least a wavelength conversion material for mixing lights of different color to provide the desired color light. The wavelength conversion material may be added to more than one place. Besides, it is also possible to add different wavelength conversion materials or the same wavelength conversion material at different places. In this embodiment, the second sealant 16 is added with the wavelength conversion material such as fluorescent powder, phosphor powder, or their combination. Of course, the wavelength conversion material may be a fluorescent tape, which can be directly attached on the outer surface of the second sealant 16 or between the first sealant 14 and the second sealant 16.

Since the second sealant 16 is directly contact the first sealant 14, and their materials are similar, the second sealant 16 can provide better adhesive force. Thus, the first sealant 14 may function as an adhesive auxiliary. For example, a thin layer of the first sealant 14 is disposed to cover the LED die 12 in advance, and then the second sealant 16 is provided thereon. The thickness of the second sealant 16 is larger than that of the first sealant 14, and the second sealant 16 totally covers the LED die 12. Accordingly, the configuration of the first sealant 14 can increase the adhesion of the second sealant 16.

To be specified, the sealant align layer 13 and the metal material (e.g. wires or die pad) within the die disposing area 111 can be formed in a single manufacturing process. For example, the die disposing area 111 and the sealant align layer 13 is formed by a screen printing process with the same mask. The die disposing area 111 is located at a center area surrounding by the sealant align layer 13. Besides, since the first sealant 14 and/or the second sealant 16 are aligned or restricted by the sealant align layer 13 during the gluing process, the LED die 12, which is disposed on the die disposing area 111, is located at the center of the first sealant 14 and/or the second sealant 16. This configuration can prevent the overlap error caused by the conventional gluing process, which separately disposes the glue and the metal material of the die disposing area 111. The overlap error may result in the LED die 12 that is shifted away from the center of the first sealant 14 and/or the second sealant 16, which usually affects the light shape and chromaticity of light emitted from the LED die 12.

FIG. 4B is a side view of another light-emitting apparatus 1c with light convergence function according to the embodiment of the invention. In this case, the first sealant 14a includes the wavelength conversion material such as fluorescent powder, phosphor powder, or their combination. The second sealant 16a has the function of protecting the first sealant 14a and is light permeable. The thickness of the second sealant 16a is larger than that of the first sealant 14a. In addition, the second sealant 16a may be properly designed to provide the light convergence or divergence function. For example, as shown in FIG. 4B, the design may fit the calculation result based on the distance x between the top point 161 of the second sealant 16a and the surface of the LED die 12 and the distance y between the side surface of the LED die 12 and the outer edge of the sealant align layer 13. In this embodiment, since the distance x is larger than the distance y, the second sealant 16a is designed to have the light convergence function.

FIG. 4C is a side view of another light-emitting apparatus 1d with light divergence function according to the embodiment of the invention. Similar to the aspect shown in FIG. 4B, the first sealant 14a of FIG. 4C includes the wavelength conversion material such as fluorescent powder, phosphor powder, or their combination. Besides, the second sealant 16b has the function of protecting the first sealant 14a and is light permeable. The difference is that the thickness of the second sealant 16b is smaller than that of the first sealant 14a. In addition, the distance x between the top point 161 of the second sealant 16b and the surface of the LED die 12 is smaller than the distance y between the side surface of the LED die 12 and the outer edge of the sealant align layer 13. Thus, the second sealant 16b is designed to have the light divergence function.

Moreover, it is possible to further dispose an additional sealant on the second sealant 16, 16a or 16b according to the actual needs.

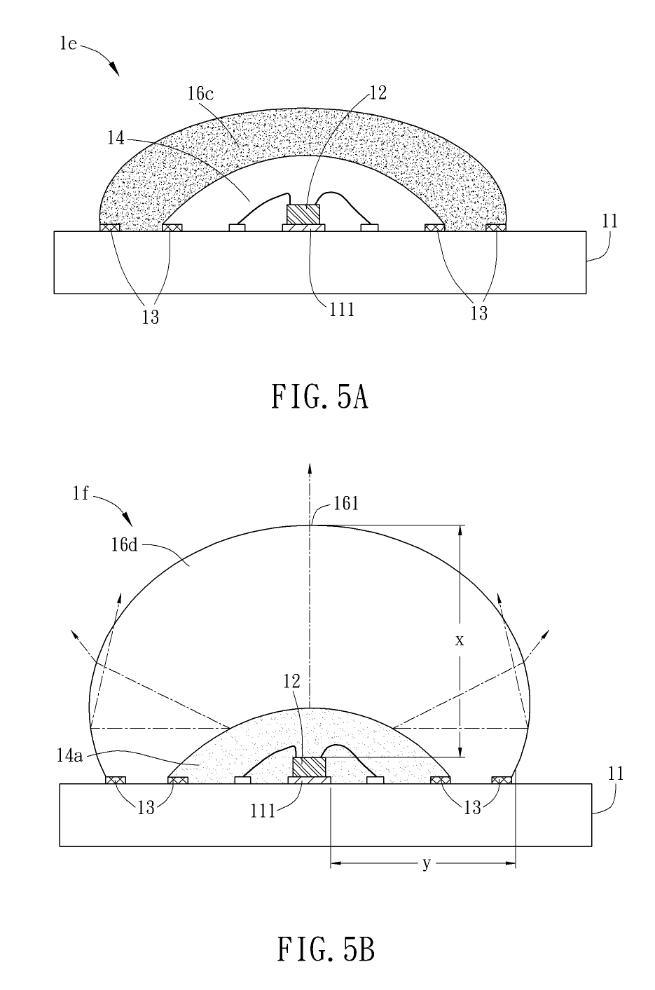

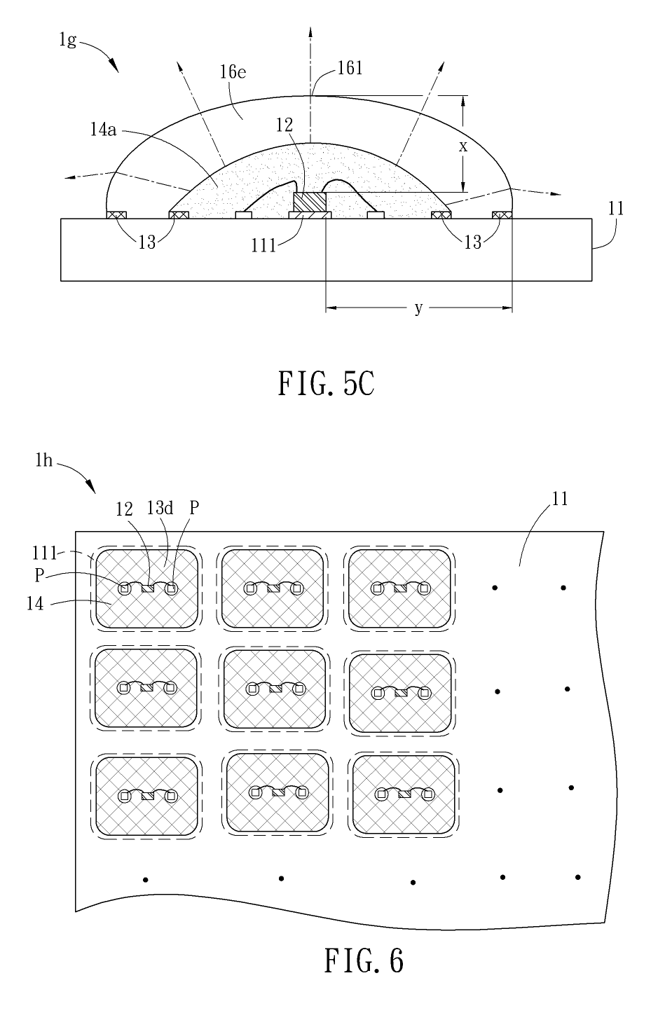

FIG. 5A is a side view of another light-emitting apparatus 1e according to the embodiment of the invention. Different from the light-emitting apparatus 1b of FIG. 4A, the light-emitting apparatus 1e includes a plurality of sealant align layers 13, and the number of the sealant align layers 13 is not limited. In this embodiment, the light-emitting apparatus 1e includes two annular sealant align layers 13. The first sealant 14 is aligned with the annular sealant align layer 13 with smaller diameter, and the second sealant 16c is aligned with the annular sealant align layer 13 with larger diameter. The die disposing area 111 is disposed at the center surrounded by the sealant align layers 13. The related manufacturing processes are all illustrated hereinabove, so the detailed description thereof is omitted. In this case, the configuration of the multiple sealant align layers 13 can further eliminate the overflow issue.

FIG. 5B is a side view of another light-emitting apparatus if with light convergence function according to the embodiment of the invention. Different from the light-emitting apparatus 1e of FIG. 5A, the first sealant 14a includes the wavelength conversion material such as fluorescent powder, phosphor powder, or their combination. The second sealant 16d has the function of protecting the first sealant 14a and is light permeable. The thickness of the second sealant 16d is larger than that of the first sealant 14a. In addition, as shown in FIG. 5B, the design may fit the calculation result based on the distance x between the top point 161 of the second sealant 16d and the surface of the LED die 12 and the distance y between the side surface of the LED die 12 and the outer edge of the sealant align layer 13. In this embodiment, since the distance x is larger than the distance y, the second sealant 16d is designed to have the light convergence function.

FIG. 5C is a side view of another light-emitting apparatus 1g with light divergence function according to the embodiment of the invention. Similarly, the first sealant 14a includes the wavelength conversion material such as fluorescent powder, phosphor powder, or their combination. Besides, the second sealant 16e has the function of protecting the first sealant 14a and is light permeable. The thickness of the second sealant 16e is smaller than that of the first sealant 14a. In addition, as shown in FIG. 5C, the distance x between the top point 161 of the second sealant 16e and the surface of the LED die 12 is smaller than the distance y between the side surface of the LED die 12 and the outer edge of the sealant align layer 13. Thus, the second sealant 16e is designed to have the light divergence function.

Moreover, it is possible to further dispose an additional sealant on the second sealant 16c, 16d or 16e according to the actual needs.

FIG. 6 is a top view of another light-emitting apparatus 1h according to the embodiment of the invention. In this aspect, a plurality of LED dies 12 are disposed on the substrate 11 and arranged in an array. The substrate 11 may be, for example but not limited to, a printed circuit board containing plastic material or a metal substrate. In this case, the substrate 11 is a printed circuit board containing plastic material. The LED dies 12 can be arranged in a row, in annular or in random, and the shape of the substrate 11 may include polygon, circle, or any other shapes. To be noted, each of the sealant align layers 13d is a metal sheet or a metal layer made of, for example, copper, silver, gold or their combination, and it is larger than the LED die 12 and smaller than the die disposing area 111 (indicated by dotted lines). In other words, the sealant align layers 13d is located within the die disposing area 111. For example, the sealant align layers 13d is a copper foil made of copper metal, and the sealant align layers 13d are arranged in an array with respect to the LED dies 12. Herein, each sealant align layer 13d is arranged with respect to one LED die 12. Of course, each sealant align layer 13d may be arranged with respect to multiple LED dies 12. Besides, when the sealant align layer 13d is made of metal material, the isolated conductive pad P and via are configured within the sealant align layer 13d for preventing the short-circuit issue. Herein, the isolated conductive pad P and the via are connected to each other. When the LED die 12 is wire bonded on the conductive pad P, it can be electrically connected to other circuits through the via and the substrate 11.

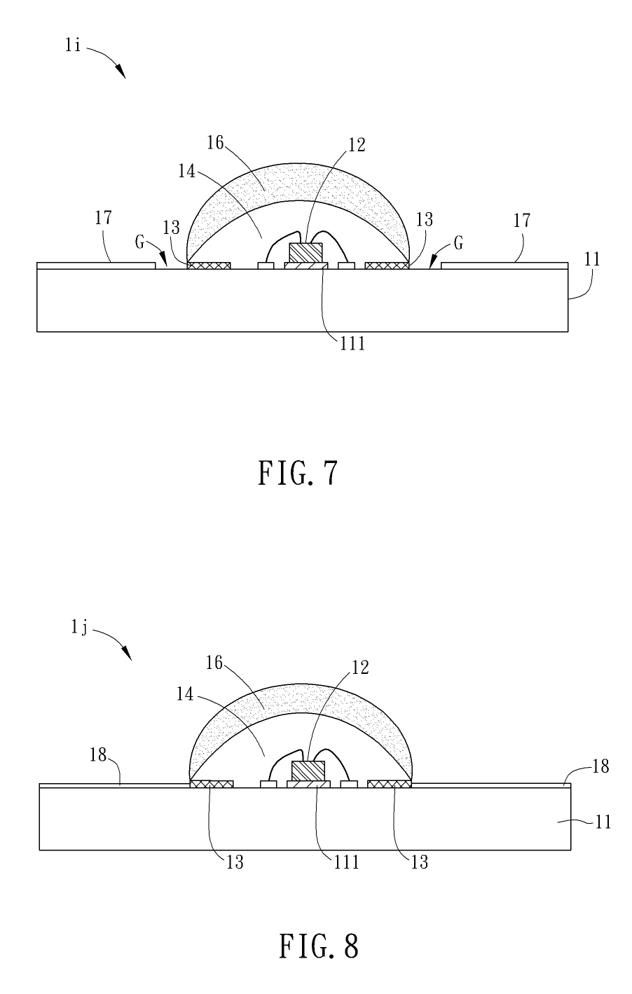

FIG. 7 is a side view of another light-emitting apparatus 1i according to the embodiment of the invention. Referring to FIG. 7, the light-emitting apparatus 1i further includes a barrier layer 17 disposed on the substrate 11 and located at the same side of the substrate 11 as the sealant align layer 13. A gap G is disposed between the barrier layer 17 and the sealant align layer 13. The material of the barrier layer 17 comprises a metal, an alloy, a solder mask, or their combinations. In this aspect, the barrier layer 17 is a metal layer. When the amount of the first sealant 14 and/or the second sealant 16 is too much and they overflow out of the range of the sealant align layer 13, the gap G and the barrier layer 17 can limit the overflowed sealant by accommodating the excess first sealant 14 and/or second sealant 16 in the gap G. Herein, the capacity for accommodating the excess sealant is depending on the size of the gap G rather than the height of the barrier layer 17. Thus, the height of the barrier layer 17 may be smaller than, equal to or larger than that of the sealant align layer 13. In this aspect, the height of the barrier layer 17 is equal to that of the sealant align layer 13.

FIG. 8 is a side view of another light-emitting apparatus 1j according to the embodiment of the invention. With reference to FIG. 8, the light-emitting apparatus 1j further includes a material layer 18 disposed on the substrate 11 and abutting against the sealant align layer 13. The material of the material layer 18 may includes a metal, an alloy, a solder mask, or their combinations. Otherwise, the material layer 18 may be a part of the substrate 11, such as the reflective metal layer, circuit layer, solder resist layer of the substrate 11. In this aspect, the material layer 18 is made of a solder mask. The height of the material layer 18 is smaller than that of the sealant align layer 13. Rather than functioning as the barrier for stopping the overflowed sealant, the material layer 18 is configured to prevent the light emitted from the LED die from leaking toward the substrate through the edge of the sealant align layer 13. Accordingly, the material layer 18 must be abutted against the sealant align layer 13.

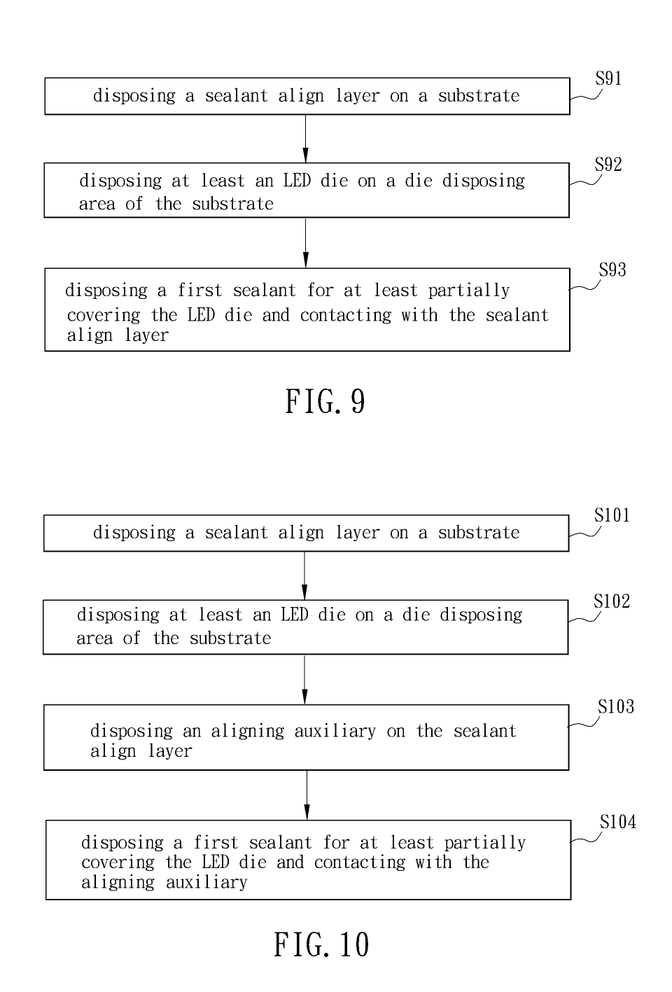

FIG. 9 is a flow chart of a manufacturing method of the light-emitting apparatus 1 (see FIG. 2) according to an embodiment of the invention. The manufacturing method includes the steps S91 to S93. In the step S91, a sealant align layer 13 is disposed on a substrate 11. In the step S92, at least an LED die 12 is disposed on a die disposing area 111 of the substrate 11. In the step S93, a first sealant 14 is provided for at least partially covering the LED die 12 and contacting with the sealant align layer 13.

FIG. 10 is a flow chart of another manufacturing method of the light-emitting apparatus 1a (see FIG. 3) according to the embodiment of the invention. The manufacturing method includes the steps S101 to S104. In the step S101, a sealant align layer 13 is disposed on a substrate 11. In the step S102, at least an LED die 12 is disposed on a die disposing area 111 of the substrate 11. In the step S103, an aligning auxiliary 15 is disposed on the sealant align layer 13. In the step S104, a first sealant 14 is provided for at least partially covering the LED die 12 and contacting with the aligning auxiliary 15.

Moreover, the manufacturing method of a light-emitting apparatus may further include a step of: disposing a second sealant 16 for covering the LED die 12 and the first sealant 14, wherein the edge of the second sealant 16 is substantially located at the edge of the sealant align layer 13; disposing a barrier layer 17 on the substrate 11, wherein the barrier layer 17 is located at the same side of the substrate 11 as the sealant align layer 13, and a gap G is disposed between the barrier layer 17 and the sealant align layer 13; and disposing a material layer 18 on the substrate 11, wherein the material layer 18 abuts against the sealant align layer 13. The above steps are all described in the above aspects of the light-emitting apparatuses 1 and 1a-1j, so the detailed descriptions thereof are omitted.

In summary, the light-emitting apparatus of the invention has a sealant align layer disposed on the substrate. Accordingly, it is possible to decrease the undesired glue overflow by aligning the sealant(s) with the sealant align layer, wherein the edge of the sealant(s) is substantially located at the edge of the sealant align layer. As a result, it is unnecessary to configure the reflective housing for carrying the LED die, so that the light outputting angle of the LED die is not decreased by the reflective housing, thereby enhancing the product quality.

Although the invention has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the invention.

What is claimed is:

1. A light-emitting apparatus, comprising:
a substrate having a die disposing area;
at least a light emitting diode (LED) die disposed on the die disposing area;
a sealant align layer disposed on the substrate; and
a first sealant at least partially covering the LED die and contacting with the sealant align layer.

2. The light-emitting apparatus of claim 1, further comprising:
a second sealant covering the LED die and the first sealant.

3. The light-emitting apparatus of claim 2, wherein the edge of the second sealant is substantially located at the edge of the sealant align layer.

4. The light-emitting apparatus of claim 2, wherein the second sealant covers the sealant align layer and is substantially located at the outer edge of the sealant align layer.

5. The light-emitting apparatus of claim 1, wherein the material of the sealant align layer comprises a metal, an alloy, or a solder mask.

6. The light-emitting apparatus of claim 1, wherein the sealant align layer is a patterned layer.

7. The light-emitting apparatus of claim 1, wherein the sealant align layer is disposed around the die disposing area.

8. The light-emitting apparatus of claim 1, wherein the sealant align layer is located within the die disposing area.

9. The light-emitting apparatus of claim 1, further comprising:
a barrier layer disposed on the substrate and located at the same side of the substrate as the sealant align layer.

10. The light-emitting apparatus of claim 9, wherein a gap is disposed between the barrier layer and the sealant align layer.

11. The light-emitting apparatus of claim 9, wherein the material of the barrier layer comprises a metal, an alloy, a solder mask, or their combinations.

12. The light-emitting apparatus of claim 1, further comprising:
a material layer disposed on the substrate and abutting against the sealant align layer.

13. The light-emitting apparatus of claim 12, wherein the height of the material layer is smaller than that of the sealant align layer.

14. The light-emitting apparatus of claim 3, wherein the first sealant and/or the second sealant comprises a wavelength conversion material.

15. A light-emitting apparatus, comprising:
a substrate having a die disposing area;
at least a light emitting diode (LED) die disposed on the die disposing area;
a sealant align layer disposed on the substrate;
an aligning auxiliary disposed on the sealant align layer; and
a first sealant at least partially covering the LED die and contacting with the aligning auxiliary.

16. A manufacturing method of a light-emitting apparatus, comprising the steps of:
disposing a sealant align layer on a substrate;
disposing at least a light emitting diode (LED) die on a die disposing area of the substrate; and
disposing a first sealant for at least partially covering the LED die and contacting with the sealant align layer.

17. The method of claim 16, further comprising a step of:
disposing a second sealant for covering the LED die and the first sealant, wherein the edge of the second sealant is substantially located at the edge of the sealant align layer.

18. The method of claim 16, further comprising a step of:
disposing a barrier layer on the substrate, wherein the barrier layer is located at the same side of the substrate as the sealant align layer.

19. The method of claim 18, wherein a gap is disposed between the barrier layer and the sealant align layer.

20. The method of claim 16, further comprising a step of:
disposing a material layer on the substrate, wherein the material layer abuts against the sealant align layer.
